(19) United States
(12) Patent Application Publication
(10) Pub. No.: US 2006/0205204 A1
(43) Pub. Date: Sep. 14, 2006

(54) Method of making a semiconductor interconnect with a metal cap

(76) Inventor: Michael Beck, Poughkeepsie, NY (US)

Correspondence Address: SLATER & MATSIL LLP, 17950 PRESTON ROAD, SUITE 1000, DALLAS, TX, 75252, US

(21) Appl. No.: 11/079,843

(22) Filed: Mar. 14, 2005

(51) Int. Cl. H01L 21/4763

(52) U.S. Cl. 438/628; 438/638

(57) ABSTRACT

A method for forming metallization is particularly useful for semiconductor devices having a critical dimension of less than 160 nm. A semiconductor wafer includes an insulating layer having an upper surface. First and second trenches are formed in the insulating layer. In one embodiment, the first trench is separated from the second trench by less than 160 nm. A barrier material is formed to line the trenches and also overlies the insulating layer between the trenches. A conductive material (e.g., copper) is formed within the trenches. The conductive material is then recessed within the trenches and a metal cap layer is selectively formed over the conductive material in the trenches. The barrier material overlying the insulating layer between the first trench and the second trench is then removed. This removal will further remove any residual portions of the metal cap layer from between the first trench and the second trench.

### TECHNICAL FIELD

This invention relates generally to semiconductor devices, and more particularly to a method of making a semiconductor interconnect with a metal cap.

### BACKGROUND

As Ultra Large Scale Integration (ULSI) circuit density increases and device feature sizes approach 0.18 microns or less, increased numbers of patterned metal levels are required with decreasing spacing between metal lines at each level to effectively interconnect discrete semiconductor devices on the semiconductor chips. Typically, the different levels of metal interconnections are separated by layers of insulator material. These interposed insulating layers have etched holes filled with a conductive material, referred to as vias, which are used to connect one level of metal to the next. Typically, the insulating layer is silicon oxide (SiO₂) having a dielectric constant k (relative to vacuum) of about 4.0 or 4.5.

However, as semiconductor device dimensions decrease and the packing density increases, it is necessary to reduce the spacing between the metal lines at each level of the interconnection to effectively wire up the integrated circuits. Unfortunately, as the spacing decreases, the intralevel and interlevel capacitances increase between metal lines, because the capacitance C is inversely proportional to the spacing d between the lines. Therefore, it is desirable to minimize the dielectric constant k of the insulating material (dielectric) between the conducting lines, in order to reduce the RC time constant and thereby increase the performance of the circuit, e.g., the frequency response, since the signal propagation time in the circuit is adversely affected by the RC delay time.

To achieve an insulating layer with a dielectric constant of 3 or less, relatively porous spin-on insulating films are commonly used, such as hydrogen silsesquioxane (HSQ), a silicon polymer with a k of 2.3-3.0, and JSR LKD-5109™, which is a trademark of the JSR Corporation, having a k of 2.35. However, these low-k insulators (low compared to silicon oxide) are usually mechanically weak and some are porous and therefore, do not provide good structural support for integration. Further, absorbed moisture and other chemicals in the porous insulator can cause corrosion of the metal lines. Low-k materials, such as, Black Diamond™, a trademark of Applied Materials, Coral™, a trademark of Novellus, SiCOH and other similar materials are used in the semiconductor industry but are deposited by CVD, which distinguishes them from the spin-on dielectrics.

Copper is the preferred metal that is used on chip multilevel interconnections (both wiring and plugs) to replace aluminum, which has a higher bulk electrical resistivity and a low resistance to electromigration. Copper can be deposited by either electrolytic or electroless deposition and also by Chemical Vapor Deposition (CVD) and Physical Vapor Deposition (PVD), as examples.

However, copper has relatively poor resistance to corrosion. Unlike other metal oxidation (such as aluminum oxidation), copper is readily oxidized to form Cu₂O and CuO at relatively low temperatures, e.g., below 200 degrees C., and no self-protective oxide layer forms to prevent the copper from further oxidation. Oxidized copper degrades the electrical and mechanical properties of the copper interconnect. Accordingly, a protection, or encapsulation, e.g., diffusion barrier, layer of high corrosion resistance material is necessary to cover exposed copper surfaces.

A variety of materials are known for forming diffusion barriers on copper. Such materials include Ta, W, Mo, TiW, TiN, TaN, WN, TiSiN and TaSiN, as examples, which can be deposited by CVD or PVD. More recently, electrolessly deposited CoWP has been used as a barrier material to encapsulate a conductor material. Furthermore, the W in the CoWP significantly enhances the barrier properties.

However, in very narrow spaces like those found between first level metal lines in 0.130 or less micron technologies, if the copper diffusion barrier cap layer is selectively deposited onto the exposed copper of the previously planarized surface there is some lateral (sideways) growth which is proportional to the thickness of the selectively deposited layer. When the lateral growth exceeds half the distance between copper lines, the cap layer can make contact with the adjacent cap layer to create an electrical short. Therefore, in some technologies a very thin layer of CoWP, proposed to achieve an improvement in electromigration, would be less prone to form electrical shorts.

### SUMMARY OF THE INVENTION

In one aspect, the present invention provides a method for forming interconnects, which is particularly useful in very small dimension devices. One way to improve the capacitive delay in the chip level interconnect is to have a smaller bulk dielectric constant in the intermetal dielectrics. In order to keep the overall effective dielectric constant small, the support dielectric layers as caps preferably have either a very low dielectric constant or are eliminated. In one aspect, the present invention provides a metal cap that will replace a dielectric cap layer. This metal cap has the same desired properties as an etch stop or oxidation barrier as the dielectric cap.

In a first embodiment, a method for forming metallization is particularly useful for semiconductor devices manufactured at a process node of 90 nm or less. A semiconductor wafer includes an insulating layer having an upper surface. First and second trenches are formed in the insulating layer. In one embodiment, the first trench is separated from the second trench by less than 150 nm. A barrier material is formed to line a bottom surface and sidewall surfaces of the first trench and the second trench. The barrier layer also overlies the insulating layer between the first trench and the second trench. A conductive material is formed within the first and second trenches and over the insulating layer between the first trench and the second trench. The conductive material is planarized to fill the first trench and the second trench. The planarizing exposes the barrier material overlying the insulating layer between the first trench and the second trench. The conductive material is recessed within the first trench and the second trench and a metal cap layer is selectively formed over the conductive material in the first trench and the second trench. The barrier material overlying the insulating layer between the first trench and the second trench is then removed. This removal will further remove any residual portions of the metal cap layer from between the first trench and the second trench.

This process can be advantageous because the previously used dielectric cap can be removed, thereby lowering the overall dielectric constant of the intermetal dielectrics. In addition, short circuits between closely spaced conductive lines are avoided without the need for additional processing steps. The metal lines, e.g., Cu, with such kind of metal cap show a much higher reliability and are able to withstand the electro-migration much longer than lines with dielectric caps.

The details of one or more embodiments of the invention are set forth in the accompanying drawings and the description below. Other features, objects, and advantages of the invention will be apparent from the description and drawings, and from the claims.

### DESCRIPTION OF THE DRAWINGS

For a more complete understanding of the present invention, and the advantages thereof, reference is now made to the following descriptions taken in conjunction with the accompanying drawings, in which:

FIG. 1 illustrates a cross-sectional view of an integrated circuit structure of a first embodiment of the invention;

FIGS. 2-10 illustrate cross-sectional views during various stages of fabrication of the structure of FIG. 1; and

FIGS. 11a and 11b illustrate an embodiment where conductive shorts between conductor-filled recesses can be avoided.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a dual damascene metallization scheme. The invention may also be applied, however, to other interconnect structures. For but two examples, the process can be applied to a single damascene metallization process or to the formation of a via or contact.

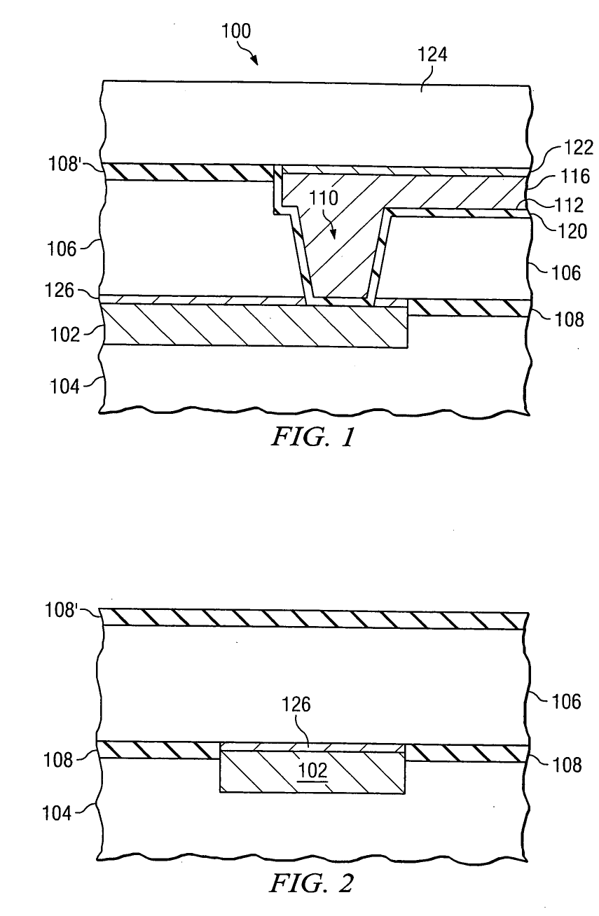

A preferred embodiment interconnect structure is illustrated in FIG. 1. One embodiment for fabricating this structure is illustrated in FIGS. 2-10. As will be explained below, and as would be understood by one of ordinary skill in the art, various modifications of the specific structure and process are possible.

Referring first to FIG. 1, an interconnect structure 100 is formed over a semiconductor wafer. While not illustrated, the semiconductor typically includes a number of active circuit components formed in a semiconductor body. The semiconductor body can be a bulk substrate (e.g., monocrystalline silicon) or a semiconductor-over-insulator (SOI) layer, as just two examples. The active circuit components preferably comprise transistors. Other components such as diodes, resistors and capacitors can also be formed.

In a first embodiment, the interconnect structure 100 includes a first metal region 102 that is surrounded by dielectric material 104. In the typical case, the first metal region 102 is part of a first metal layer that was formed as one of a number of metallization levels in an integrated circuit. As an example, the first metal layer can be the first metal layer over the active components (often referred to as metal 1). In other examples, the metal layer can be an upper metal layer (e.g., metal 2 or metal 5, as arbitrary examples).

In the preferred embodiment, the first metal region 102 is a copper damascene (either single damascene or dual damascene) interconnect. As such, the first metal region 102 is embedded in dielectric 104. In other embodiments, the first metal region 102 can be a different material such as aluminum, tungsten or gold and may be embedded in two separate layers.

In the preferred embodiment, the first metal region 102 includes a metal cap 126. The preferred formation of the metal cap 126 is preferably the same as metal cap 122, which will be described below. In an alternate embodiment, not shown, the first metal region 102 can be capped with a dielectric cap, which would extend all the way over the wafer, except where etched to expose the first metal region 102 for contact 110.

In an alternate embodiment, the conductive region 102 can be a conductor other than a metal, e.g., doped polysilicon or silicon. For example, a highly doped semiconductor region 102 can be formed in the semiconductor body of the opposite conductivity type. For example, the region 102 can be a source or drain region of a transistor. As another example, the region 102 can be a plug, e.g., a tungsten plug that is electrically coupled to the semiconductor body.

For purposes of illustration, the remainder of the discussion will assume that conductive region 102 is a metal conductor. It is understood, however, that aspects of the invention can be applied in other interconnect levels of the chip.

Dielectric layer 106 overlies the first conductive region 102 and the dielectric material 104. The dielectric layer 106 can comprise any dielectric material such as an oxide (e.g., SiO₂) or a doped oxide (e.g., PSG, BPSG, FSG, or BSG). In the preferred embodiment, dielectric layer 106 comprises a low-k dielectric. In this context, a low-k dielectric, which can be either porous or non-porous, is a dielectric that has a dielectric constant less than the dielectric constant of undoped silicon dioxide. The low-k dielectric material can be an organic spin-on material such as a polyimide or others. Examples of porous low-k dielectric include JSR LKD-5109™ available from JSR Corporation and Flare™ available from Allied Signal Inc. In the preferred embodiment, the dielectric 106 is formed from SiCOH, either dense SiCOH or porous SiCOH (pSiCOH).

A dielectric layer 108 is optionally included between the dielectric 104 and the dielectric 106. This dielectric 108 serves as a hard mask to protect the dielectric 104 during the chemical mechanical polishing step that completes formation of metal region 102. Layer 108 can also, or alternatively, serve as a barrier for some porous low-k materials to prevent moisture from coming into the dielectric 104. For some embodiments that do not require this function, the layer can be omitted. The dielectric 108 can include one or more of a nitride layer (e.g., Si₃N₄), an oxynitride layer (e.g., SiON), an oxide layer (e.g., SiO₂), a dense oxide layer, or other material. In the preferred embodiment, the hard mask layer 108 is formed from a SiCN material, such as NBLOK™.

The first dielectric layer 106 includes a via hole 110 that provides access to the metal region 102. The via hole 110 may be any size to accommodate the design but is typically at the design minimum. For example, the process and structure taught herein is particularly useful at small dimensions of less than 90 nm (e.g., 65 nm, 45 nm or below). The via hole 110 may be formed in any of a number of shapes as viewed from a plan view (not shown) but is typically circular or elliptical.

In the preferred embodiment, the dielectric layer 106 also includes a trench 112 that is filled with conductive material 116. The conductive material 116 preferably forms a metal region and is part of a second metal layer relative to the first metal layer 102 (i.e., if region 102 is part of metal 3 than region 116 is part of metal 4). The metal region 116 is preferably formed from the same material (e.g., copper) as contact and physically contacts the conductive contact in hole 110.

Although not shown, an additional dielectric layer is optionally included within dielectric layer 106 at the lower surface of the trench 112. If included, the additional dielectric layer is preferably a different material than either of the adjacent dielectrics and may serve as an etch stop layer, which is useful in forming the via and trench, as a cap layer, as a diffusion barrier, as a passivation layer, or as combinations of these functional layers. As with dielectric 108, this additional dielectric layer can include more than one layer of materials. For example, the dielectric layer can include one or more of a nitride layer (e.g., Si₃N₄), an oxynitride layer (e.g., SiON), an oxide layer (e.g., SiO₂), a dense oxide layer, or other material. In the preferred embodiment, this layer is eliminated since it will raise the overall dielectric constant of the interlevel dielectric 106 in which it is embedded.

A liner 120 separates the metal material 116 from the surrounding dielectric 106. The liner 120 preferably comprises a diffusion barrier that prevents metal from the interconnect structure 100 from migrating into the adjacent insulators. For example, when a copper interconnect is used, the liner may be a material such as tantalum, tantalum nitride, titanium, titanium nitride, titanium tungsten, tungsten nitride, ruthenium, iridium or platinum. As shown in FIG. 1, the liner 120 is disposed between the conductive contact 116 and the dielectric layer 106 and also between the metal region 116 and the metal region 102. In another embodiment (not shown), the liner 120 does not extend between the conductive contact 116 and the metal region 102. Such an embodiment is disclosed in co-pending application Ser. No. ______ (2004 P 54932), which is incorporated herein by reference.

A metal cap layer 122 is formed over the metal region 116. The metal cap can serve as an etch stop or oxidation barrier, as but two examples. An additional, or alternate, feature of the metal cap 122 is that it can enhance electro-migration. For example, the cap will suppress copper migration much more than dielectric caps and will, therefore, allow a higher current density in the metal line. In the preferred embodiment, the metal cap is formed from CoWP. In other embodiments, the cap can be formed from CoWB, CoP, NiMoP, Re or Ru.

A dielectric 124 is formed over the metal region 116 and the dielectric 106 (and hard mask 108′). The dielectric 124 is preferably an intermetal dielectric of the same material as dielectric 104 and 106. While not shown, a third metal level can be formed in dielectric 124, e.g., using the same process as will now be described in FIGS. 2-10.

A preferred method of forming the structure of FIG. 1 will now be described with respect to FIGS. 2-10. These figures provide but one example of the process steps. As will be recognized by one of skill in the art, a number of alternatives are possible. For example, while this process flow shows a via first dual damascene process, it is well understood that a trench first (or via last) process flow would work equally as well.

Referring now to FIG. 2, a partially fabricated integrated circuit is shown. This structure includes metal region 102, which is formed within dielectric layer 104. In the preferred embodiment, the metal region 102 is a copper line formed by a damascene process (either single damascene or dual damascene).

In this particular embodiment, two dielectric layers cover the dielectric layer 104 (and 108) and metal line 102. In particular, the inter metal dielectric (IMD) 106 and the hard mask layer 108′ are formed. Intermetal dielectric layer 106 can have a thickness of between about 250 nm and about 500 nm, for example 270 nm. In the preferred embodiment, this dielectric is dense SiCOH. In other embodiments, other dielectrics can be used. The layer 106 is preferably a low-k dielectric. Examples of porous low-k dielectrics that can be used are pSiCOH, JSR LKD-5109™, and FLARE™. As discussed above, other materials can alternatively be used.

The hardmask layer 108 (and 108′) is typically made as thin as possible. In fact, this layer 108 can be eliminated if the CMP process, which will be described with respect to FIG. 10, can be controlled so as to avoid damage to IMD 106 and a moisture barrier is not needed for IMD 106. When included, the hardmask layer 108 can be deposited to a thickness of 60 nm or more. After CMP, the hardmask layer will typically have a thickness of between about 10 nm to about 20 nm.

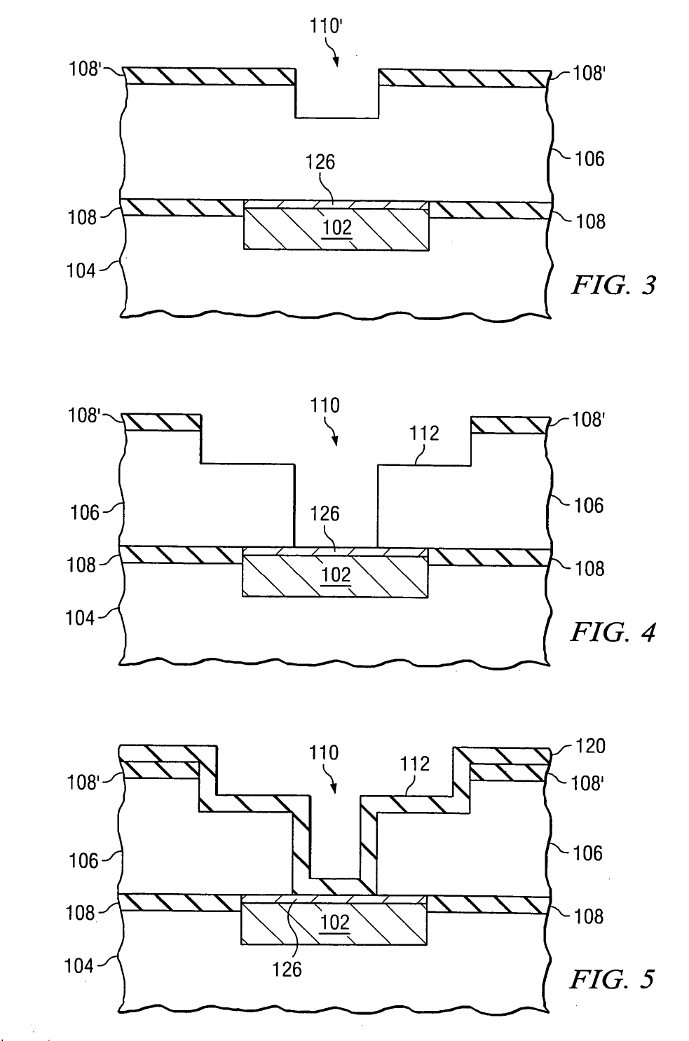

FIGS. 3 and 4 illustrate the formation of the dual damascene structure, which includes a via hole 110 and a trench 112. The trench 112 is one of a number of trenches formed in dielectric layer 106 in the pattern of the metal interconnects. This pattern is determined by the circuit design and necessary interconnections. The via hole 110 is one of number of via holes that will provide a connection between the conductor to be formed in trench 112 with the conductors of underlying structures (e.g., metal line 102).

In the particular embodiment of FIGS. 3 and 4, an opening 110′ is formed in an upper portion of dielectric layer 106. Opening 110′ is provided in the same location and has the same dimensions of via hole 110, which will be formed in the lower portion of layer 106. The opening 110′ is formed by patterning (e.g., with a mask that is not shown) the dielectric layer 106 and performing a timed etch until the proper depth is reached. In alternative embodiments (not shown), the opening 110′ can be formed all the way to layer 102 or until reaching an etch stop layer (not shown). The etching step is preferably an anisotropic etch performed by reactive ion etching (RIE).

Referring now to FIG. 4, a second lithography step is performed to etch the trench 112 in the dielectric layer 106. Once again a mask (not shown) is used to etch dielectric layer 106 until the proper depth is reached. This etching step is preferably a timed etch and etches to a depth of between about 100 nm and about 250 nm. Alternatively, the etch is performed until reaching an etch stop layer (not shown). While etching the trench, the exposed portions of dielectric layer 106 within opening 110′ will be etched until reaching the conductive layer 102 (or metal cap 126, if included).

FIG. 4 shows the resulting structure. As noted above, this structure could be formed by a number of processes. The particular process described herein is provided merely as an example.

Referring now to FIG. 5, a liner 120 is formed over the surface of the structure. As shown, the liner 120 extends over the upper surface of dielectric layer 106, along sidewall surfaces of the trench 112, over the lower surface of the trench 112, along sidewall surfaces of the via hole 110 and on the upper surface of the copper interconnect line 102. The liner 120 typically comprises a refractory metal or a compound thereof such as tantalum, titanium, tantalum nitride, titanium nitride, titanium tungsten, tungsten nitride, iridium, ruthenium, platinum or combinations thereof. In the preferred embodiment, a tantalum nitride layer is deposited by atomic layer deposition (ALD) to a thickness of between about 1 nm and 5 nm (preferably about 2 nm). The liner 120 can extend through the metal cap 126 (as shown in the embodiment of FIG. 1) or can directly contact conductive region 102 through the cap layer 126 (as shown in FIG. 5).

In one embodiment, which is disclosed in co-pending application Ser. No. ______ (2004 P 54932) and which is not illustrated here, the portion of the liner material 120 that overlies the conductive region 102 is selectively removed and a recess is etched into the conductive region 102. This embodiment allows for greater adherence of the copper 116 and 102 and also removes the typically higher resistance barrier layer 120 from the electrical path between conductors. The selective removal of the barrier layer is an optional step.

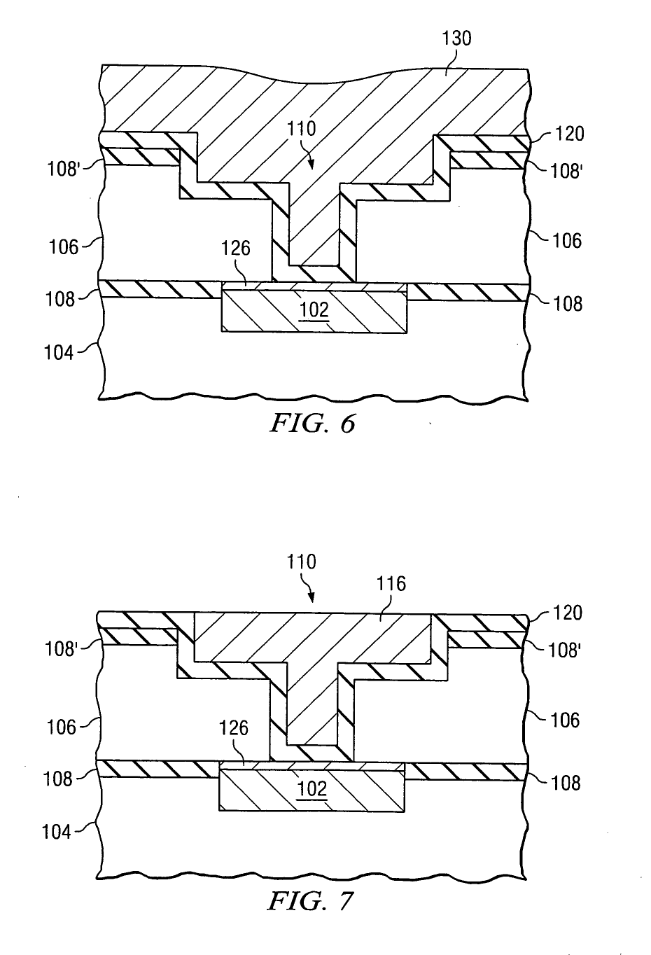

FIG. 6 illustrates that a metal (e.g., copper) 130 is deposited in the via hole 110 and the trench 112. This copper 130 will form the contact 110 and interconnect 116. In the preferred embodiment, a copper seed layer (not explicitly shown) is deposited first followed by electrodeposition or plating of copper. In another embodiment, the copper 130 can be can be electroplated directly on the liner 120 (e.g., a tantalum or ruthenium liner). In the illustrated embodiment, copper is deposited within the trench and via hole and over the upper surface of insulator 106.

The structure of FIG. 6 can then be planarized as shown in FIG. 7. In the preferred embodiment, a chemical mechanical polish (CMP) step is performed that is selective to the barrier material 120. After the CMP step, the upper surface of the metal 116 is preferably coplanar with the upper surface of the barrier 120 over the insulating layer 106.

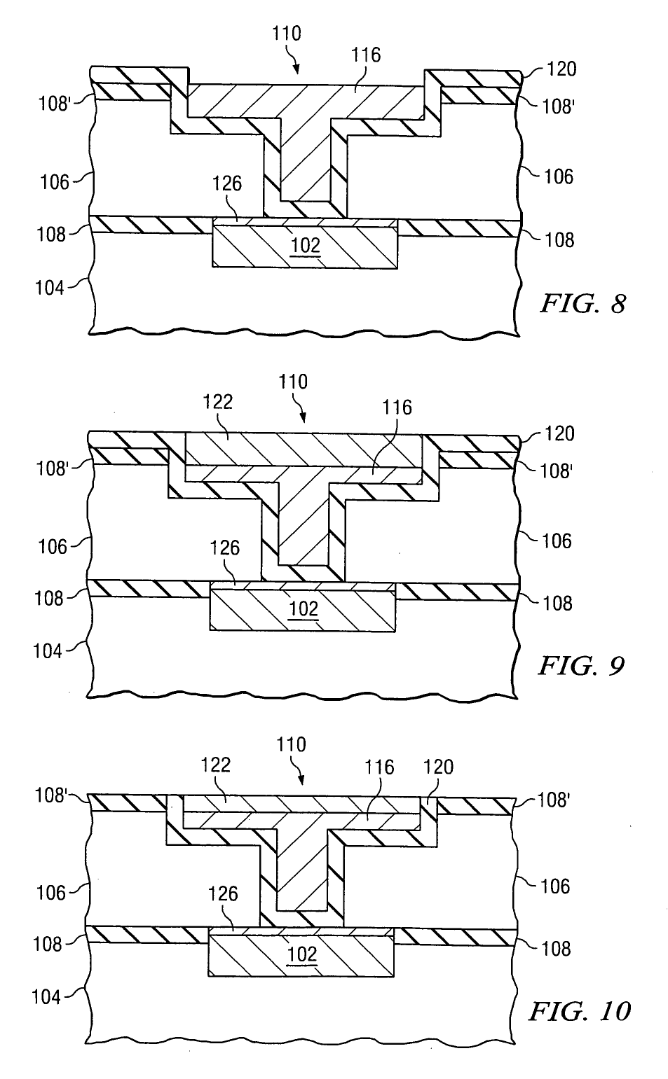

As shown in FIG. 8, an etching step is performed to recess the metal 116 within the trench 112. In particular, the copper is typically etched back by an amount equal to between about 5 nm and 20 nm (preferably about 10 nm). In one embodiment, the recess is formed by a wet etch, e.g., using ammonium persulfate, which etch should leave the liner 120 substantially intact.

Referring now to FIG. 9, the metal cap material 122 is selectively deposited. In this context, the selective deposition deposits material onto the region 116 at a rate that substantially exceeds the deposition rate of metal cap material on the liner 120 that overlies the insulating material 106. In the ideal situation, no metal cap material 122 would be deposited on the liner 120. It has been found that in practice, however, that some residue of metal cap conductor 122 will be formed over the liner 120. If this occurs, this material 122 can be removed while the liner 120 is removed, as will be discussed with respect to FIG. 10.

In the preferred embodiment, the metal cap layer 122 is formed by the selective deposition of CoWP. In other embodiments, the cap layer can be formed from CoWB, CoP, NiMoP, Re or Ru, as examples. In one exemplary embodiment, the metal cap is selectively deposited using an electroless plating process the includes two steps as follows:
1) paladium seed deposition
   3-8 ml per liter of 37% HCl solution
   0.1-0.5 grams per liter of PdCl₂
   Time: 10-60 seconds
2) CoWP cap deposition
   0.1-0.2 grams per liter NaH₂PO₂ (Hypophosphite-based bath)
   0.05-0.1 grams per liter CoSO₄
   4-6 grams per liter DMAB (dimethyl amine borane=DMAB)
   0.01-0.05 grams per liter Na₂WO₄ in the presence of WO₄(−2)
      pH—Value adjusted by KOH to a value between 8.5 and 9.0
   Temperature: 60-75 degrees C.
   Time: 70-150 seconds
      A DI water rinse can be applied afterwards to rinse the wafer.

FIG. 10 illustrates the removal of the liner 120 from the upper surface of dielectric 106. In the preferred embodiment, a second chemical mechanical polish step is performed to remove the liner 120 as well as any residue of the metal cap material 120 that might have been overlying the liner 120. In the one exemplary embodiment, the CMP step uses a slurry that is a mixture of 1-10% silicon compound (e.g., SiO₂) as the mechanical component, 0.1-1% organic acid (e.g., RCO₂H) as the chemical compound, and 89-98.9% purified water.

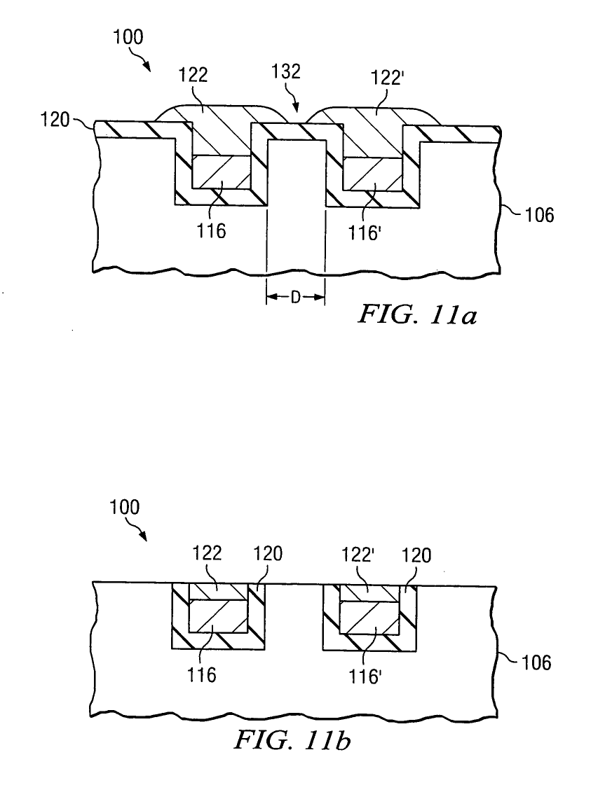

FIGS. 11a and 11b can be used to illustrate one of the advantages of the present invention. FIG. 11a shows a device 100 after the selective deposition of cap material 122 (as was discussed above with respect to FIG. 9). In this case, two adjacent interconnect structures 116 and 116′ are illustrated. In a commercial embodiment, thousands or millions of these structures would be formed. To increase the number of connections, the dimension D between interconnects is set to the lowest possible number. The dimension D shrinks as the process node decreases. For example, in a 65 nm process node (i.e., where transistors have a gate minimum gate length of 65 nm), the spacing between metal lines can be about 90 nm to 100 nm. In a 45 nm process node, the spacing between metal lines can be about 65 nm to 70 nm.

One problem that occurs when the dimension D is made too small is that residue from the selective deposition of cap material 122 can create short circuits in the area 132 between recesses. Experimentation has shown that this problem is significant at dimensions of less than 100 nm (e.g., 65 nm node or 45 nm node), that is where D≦100 nm. For example, yields of less than 50% were achieved in one experiment at 70 nm dimensions.

Use of the present invention, however, eliminates any such short. In prior art embodiments, the liner 120 is removed from between the trenches at the same time that the conductor 116 is planarized (e.g., in a two step CMP). As a result, an additional step would be required to remove any residual cap material 122. This additional step, as well as being costly, could damage the upper surface of the dielectric 106 (or require a thicker hard mask 108).

In the preferred embodiment of the present invention, however, the liner 120 is removed from the upper surface of dielectric 106 after selective deposition of the cap metal 122. As a result, any residual cap material can be removed without requiring an additional processing step or causing additional damage to the dielectric 106 (or 108′).

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for forming an interconnect, the method comprising:
providing a semiconductor wafer with an insulating layer having an upper surface;
forming a plurality of recesses in the insulating layer;
forming a barrier material over the upper surface of the insulating layer, the barrier material lining a bottom surface and sidewall surfaces of the recesses;
forming a conductive material within the recesses and over the upper surface of the insulating layer;
planarizing the conductive material so that substantially all of the conductive material is removed from over the upper surface of the insulating layer and such that an upper surface of conductive material within the recesses is substantially co-planar with an upper surface of the barrier material over the upper surface of the insulating layer;
recessing the conductive material within the recesses;
selectively forming a metal cap layer over the conductive material in the trenches; and
performing a chemical-mechanical polishing step to remove the barrier material from the upper surface of the wafer, the chemical-mechanical polishing step removing any residual portions of the metal cap layer from between the trenches.

2. The method of claim 1 wherein the insulating material comprises a low-k dielectric material.

3. The method of claim 2 wherein the insulating material comprises SiCOH.

4. The method of claim 1 wherein forming a conductive material comprises electroplating copper.

5. The method of claim 4 and further comprising forming a Cu seed layer over the barrier layer prior to electroplating copper.

6. The method of claim 4 wherein planarizing the conductive material comprises performing a chemical mechanical polish step.

7. The method of claim 4 wherein forming a barrier layer comprises forming one or more layers that include tantalum.

8. The method of claim 4 wherein the metal cap layer comprises a CoWP layer.

9. The method of claim 1 wherein forming a plurality of recesses comprises forming a plurality of trenches.

10. The method of claim 1 wherein forming a plurality of recesses comprises forming a plurality of via holes.

11. The method of claim 1 wherein forming a plurality of recesses comprises forming a plurality of dual damascene structures.

12. The method of claim 1 wherein forming a plurality of recesses comprises forming a plurality of structures having at least one feature size that is less than 90 nm.

13. A method for forming an interconnect, the method comprising:
providing a semiconductor wafer that includes an insulating layer having an upper surface;
forming a plurality of recesses in the insulating layer;
forming a barrier material over the upper surface of the insulating layer, the barrier material lining a bottom surface and sidewall surfaces of the recesses;
filling the recesses with copper, the copper being formed above an upper level of the recesses and over the upper surface of the insulating layer;
removing copper from above the upper level of the recesses and from over the upper surface of the insulating layer, the copper being removed by a chemical-mechanical polishing step, the chemical-mechanical polishing step leaving barrier material over the insulating layer between the trenches;
recessing the copper within the recesses;
selectively forming a metal cap layer over the copper in the trenches; and
after selectively forming the metal cap layer, performing a second chemical-mechanical polishing step to remove the barrier material from the upper surface of the wafer, the second chemical-mechanical polishing step removing any residual portions of the metal cap layer from between the trenches.

14. The method of claim 13 wherein selectively forming a metal cap layer comprises selectively forming a CoWP cap.

15. The method of claim 13 wherein forming a plurality of recesses comprises forming a plurality of trenches.

16. The method of claim 15 wherein ones of the plurality of trenches have a dimension that is 90 nm or less.

17. The method of claim 16 wherein the insulating layer comprises a low-k dielectric layer.

18. A method for forming metallization in a semiconductor device formed at a process node smaller than 90 nm, the method comprising:
providing a semiconductor wafer including a semiconductor material and an overlying insulating layer that includes an upper surface, the insulating layer comprising a low-k dielectric, the semiconductor wafer including a plurality of transistors, at least some of the transistors having a gate length less than 90 nm;
forming a first trench and a second trench in the insulating layer, the first trench being separated from the second trench by less than 100 nm;
forming a barrier material that lines a bottom surface and sidewall surfaces of the first trench and the second trench, the barrier layer also overlying the insulating layer between the first trench and the second trench;
forming a conductive material within the first and second trenches and over the insulating layer between the first trench and the second trench;
planarizing the conductive material to fill the first trench and the second trench, the planarizing exposing the barrier material overlying the insulating layer between the first trench and the second trench;
recessing the conductive material within the first trench and the second trench;
selectively forming a metal cap layer over the conductive material in the first trench and the second trench; and
after selectively forming the metal cap layer, removing the barrier material overlying the insulating layer between the first trench and the second trench, the removing step further removing any residual portions of the metal cap layer from between the first trench and the second trench.

19. The method of claim 18 wherein forming a conductive material comprises depositing copper.

20. The method of claim 19 wherein the first trench is separated from the second trench by no more than about 65 nm.

21. The method of claim 19 wherein removing the barrier material comprises performing a chemical mechanical polish step.

22. The method of claim 19 wherein selectively forming a metal cap layer comprises selectively forming a CoWP cap.

23. The method of claim 19 wherein the insulating layer comprises SiCOH.
